(19) United States
(12) Patent Application Publication
(10) Pub. No.: US 2025/0319794 A1
(43) Pub. Date: Oct. 16, 2025

(54) BATTERY CAPACITY ESTIMATION UNCERTAINTY

(71) Applicant: FORD GLOBAL TECHNOLOGIES, LLC, Dearborn, MI (US)

(72) Inventors: Gabrielle VUYLSTEKE, Ferndale, MI (US); Michael David BEENEY, Canton, MI (US); Arsham SHAHLARI, McKinney, TX (US)

(21) Appl. No.: 18/634,018

(22) Filed: Apr. 12, 2024

(51) Int. Cl. B60L 58/10; G01R 31/3842; H02J 7/00

(52) U.S. Cl. CPC B60L 58/10; G01R 31/3842; H02J 7/0048; H02J 7/0063

(57) ABSTRACT

An automotive power adjusts a maximum discharge power of a traction battery according to an estimated capacity. The estimate capacity depends on data of the traction battery from instances of time selected based on a delta state of charge uncertainty associated with the instances of time. The automotive power system may further store the data.

### TECHNICAL FIELD

The present disclosure relates to estimating battery capacity of an electric vehicle (EV). More specifically, the present disclosure relates to minimizing battery capacity estimation uncertainties.

### BACKGROUND

Electric vehicles rely on a traction battery for supplying electric power to an electric machine for propulsion. Over time, the capacity of the traction battery may decrease. An on-board vehicle computer may be configured to update the battery capacity.

### SUMMARY

An automotive power system includes a traction battery and a controller that adjusts a maximum discharge power of the traction battery according to an estimated capacity that depends on data of the traction battery from instances of time selected based on a delta state of charge uncertainty associated with the instances of time.

A method includes adjusting a maximum discharge power for a traction battery according to an estimated capacity that depends on data of the traction battery from instances of time corresponding to a delta state of charge uncertainty value less than a predefined threshold.

A vehicle includes an electric machine, a traction battery, and a controller that commands discharge of power from the traction battery for the electric machine according to data of the traction battery from instances of time selected based on a net amp hour throughput uncertainty associated with the instances of time.

### BRIEF DESCRIPTION OF THE DRAWINGS

FIG. 1 illustrates an example block topology of an electrified vehicle illustrating drivetrain and energy storage components.

FIG. 2 illustrates an example flow diagram of a process for determining the battery capacity and operating the vehicle.

FIG. 3 illustrates an example graph of a lookup table for battery state of charge uncertainties.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes a method and system for estimating battery capacity of an EV. More specifically, the present disclosure proposes a method and system for minimizing battery capacity estimation uncertainties.

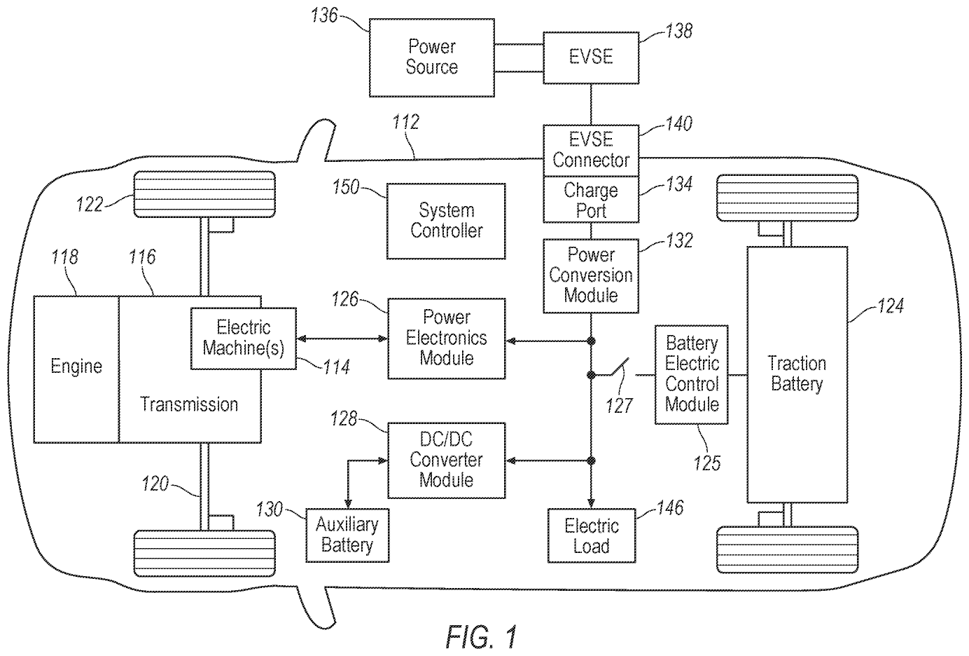

FIG. 1 illustrates a plug-in hybrid-electric vehicle (PHEV). A plug-in hybrid-electric vehicle 112 may comprise one or more electric machines (electric motors) 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to the wheels 122. The electric machines 114 may provide propulsion and slowing capability when the engine 118 is turned on or off. The electric machines 114 may also act as generators and may provide fuel economy benefits by recovering energy that would be lost as heat in the friction braking system. The electric machines 114 may also reduce vehicle emissions by allowing the engine 118 to operate at more efficient speeds and allowing the hybrid-electric vehicle 112 to be operated in electric mode with the engine 118 off under certain conditions.

A traction battery or battery pack 124 stores energy that may be used by the electric machines 114. A vehicle battery pack 124 may provide a high voltage DC output. The traction battery 124 may be electrically coupled to one or more battery electric control modules (BECM) 125. The BECM 125 may be provided with one or more processors and software applications configured to monitor and control various operations of the traction battery 124. The traction battery 124 may be further electrically coupled to one or more power electronics modules 126. The power electronics module 126 may also be referred to as a power inverter. One or more contactors 127 may isolate the traction battery 124 and the BECM 125 from other components when opened and couple the traction battery 124 and the BECM 125 to other components when closed. The power electronics module 126 may also be electrically coupled to the electric machines 114 and provide the ability to bi-directionally transfer energy between the traction battery 124 and the electric machines 114. For example, a traction battery 124 may provide DC voltage while the electric machines 114 may operate using three-phase AC current. The power electronics module 126 may convert the DC voltage to three-phase AC current for use by the electric machines 114. In a regenerative mode, the power electronics module 126 may convert the three-phase AC current from the electric machines 114 acting as generators to DC voltage compatible with the traction battery 124. The description herein is equally applicable to a pure electric vehicle. For a pure electric vehicle, the hybrid transmission 116 may be a gear box connected to the electric machine 114 and the engine 118 may not be present.

In addition to providing energy for propulsion, the traction battery 124 may provide energy for other vehicle electrical systems. A vehicle may include a DC/DC converter module 128 that converts the high voltage DC output of the traction battery 124 to a low voltage DC supply that is compatible with other low-voltage vehicle loads. An output of the DC/DC converter module 128 may be electrically coupled to an auxiliary battery 130 (e.g., 12V battery).

The vehicle 112 may be a battery electric vehicle (BEV) or a plug-in hybrid electric vehicle (PHEV) in which the traction battery 124 may be recharged by an external power source 136. The external power source 136 may be a connection to an electrical outlet. The external power source 136 may be an electrical power distribution network or grid as provided by an electric utility company. The external power source 136 may be electrically coupled to electric vehicle supply equipment (EVSE) 138. The EVSE 138 may provide circuitry and controls to manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EVSE connector 140 may have pins that mate with corresponding recesses of the charge port 134. Alternatively, various components described as being electrically coupled may transfer power using a wireless inductive coupling.

One or more electrical loads 146 may be coupled to the high-voltage bus. The electrical loads 146 may have an associated controller that operates and controls the electrical loads 146 when appropriate. Examples of electrical loads 146 may be a heating module, an air-conditioning module, or the like.

The various components discussed may have one or more associated controllers to control and monitor the operation of the components. The controllers may communicate via a serial bus (e.g., Controller Area Network (CAN)) or via discrete conductors. A system controller 150 may be present to coordinate the operation of the various components. It is noted that the system controller 150 is used as a general term and may include one or more controller devices configured to perform various operations in the present disclosure. For instance, the system controller 150 may be programmed to enable a powertrain control function to operate the powertrain of the vehicle 112. The system controller 150 may be further programmed to enable a telecommunication function with various entities (e.g., a server) via a wireless network (e.g., a cellular network).

The BECM 125 may be configured to perform various operations. For instance, the BECM 125 may be configured to perform the capacity estimation for the traction battery 124 in a periodic manner. The capacity of the traction battery 124 may reduce over time. After a period of time, the capacity of the traction battery 124 may be less than the designed capacity when the traction battery 124 is manufactured. An accurate estimation of the actual capacity may facilitate the operation and control of the vehicle 112. For instance, an accurate estimation of the actual capacity may provide the vehicle user with better range estimation and affect the charging and discharging operations.

The capacity estimation may be performed based on measurement of voltage and current charged to and/or discharged from the traction battery 124. In an example, the BECM 125 may measure an initial voltage at a first instance and a final voltage at a second instance of the traction battery via one or more voltage sensors. The voltages may be used to estimate a state of charge (SOC) of the traction battery at each corresponding instances via a look-up table (LUT). The SOC difference between the first and second instances may be recorded as a ΔSOC. The BECM 125 may further measure the current input/output of the traction battery between the first and second instances and integrate the current as measured to account for the net Amp-hour (Ah) throughput that corresponds to the ΔSOC. Then the total capacity of the traction battery may be estimated based on the ΔSOC and the net Amp-hour throughput. The above capacity estimation is associated with various uncertainties. For instance, the LUT for determining battery SOC using the battery terminal voltage may be associated with an inherent SOC uncertainty U(SOC) at each different voltage point. The inherent SOC uncertainty U(SOC) may cause an uncertainty associated with the SOC difference U(ΔSOC). Further, the net amp hour throughput measurement as calculated via the current integration may be also associated with uncertainties.

The present disclosure proposes a method for estimating the capacity of the traction battery 124 by selecting those datapoints that are associated with minimum uncertainties. More specifically, the uncertainties U(ΔSOC) associated with various ΔSOC may be estimated. The present disclosure records the battery data for trips associated with the minimum uncertainty U(ΔSOC) and disregards those battery data for trips associated with higher minimum uncertainties U(ΔSOC).

The uncertainty of the estimated capacity Q_{Est} of the traction battery 124 may be expressed using the following equations:

$$U ( {Q}_{Est} ) = 100 \% * \sqrt{{( \frac{U ( {\int }_{{CC}_{1}}^{{CC}_{2}} I dt )}{{\int }_{{CC}_{1}}^{{CC}_{2}} I dt} )}^{2} + {( \frac{\sqrt{{( U ( {SOC}_{LUT} ( V ( CC 2 ) , T ( CC 2 ) ) ) )}^{2} + {( U ( {SOC}_{LUT} ( V ( CC 1 ) , T ( CC 1 ) ) ) )}^{2}}}{{SOC}_{LUT} ( V ( CC 2 ) , T ( CC 2 ) ) - {SOC}_{LUT} ( V ( CC 1 ) , T ( CC 1 ) )} )}^{2}} * {Q}_{Est} \qquad ( 1 )$$

wherein

$${\int }_{{CC}_{1}}^{{CC}_{2}} Idt$$

denotes the integration of current (e.g., net amp hour throughput) between a first instance when the main contactor 127 is closed and a subsequent second instance when the main contactor 127 is closed. Both the first and second instances may be time points before the present time.

$$U ( {\int }_{{CC}_{1}}^{{CC}_{2}} Idt )$$

denotes the uncertainty associated with the net amp hour throughput measurement as calculated via current integration.

In the present example,

$$U ( {\int }_{{CC}_{1}}^{{CC}_{2}} Idt )$$

is very small and can be assumed as approximately equal to zero. Therefore, the above equation (1) may be simplified as:

$$U ( {Q}_{Est} ) = 100 \% * ( \frac{\sqrt{{( U ( {SOC}_{LUT} ( V ( CC 2 ) , T ( CC 2 ) ) ) )}^{2} + {( U ( {SOC}_{LUT} ( V ( CC 1 ) , T ( CC 1 ) ) ) )}^{2}}}{{SOC}_{LUT} ( V ( CC 2 ) , T ( CC 2 ) ) - {SOC}_{LUT} ( V ( CC 1 ) , T ( CC 1 ) )} ) * {Q}_{Est} \qquad ( 2 )$$

wherein SOC_{LUT}(V(CC1), T(CC1)) denotes the SOC of the traction battery 124 estimated via a SOC-OCV lookup table at the first instance. SOC_{LUT}(V(CC2), T(CC2)) denotes the SOC of the traction battery 124 estimated via the SOC-OCV lookup table at the second instance. The SOC-OCV lookup table may be stored in a non-volatile manner inside a storage of the BECM 125 and/or a storage associated with other components of the vehicle 112. Like most lookup tables, the SOC-OCV lookup table may not be 100% accurate. Thus, the SOC-OCV lookup process may be inherently associated with an uncertainty. The above equation (2) takes the uncertainty into account by introducing U(SOC_{LUT}(V(CC1), T(CC1) which reflects the uncertainty associated with the SOC-OCV lookup process at the first instance, and U(SOC_{LUT}(V(CC2), T(CC2))) which reflects the uncertainty associated with the SOC-OCV lookup process at the second instance. In an alternative example, the amp-hour integration throughput component

$$U ( {\int }_{{CC}_{1}}^{{CC}_{2}} Idt )$$

may be the dominating factor and cannot be ignored. For simplicity, the following example will be made with the amp-hour integration throughput component ignored.

The estimated capacity Q_{Est} of the traction battery 124 may be estimated using the following equation,

$${Q}_{Est} = \frac{100 \% * {\int }_{{CC}_{1}}^{{CC}_{2}} Idt}{{SOC}_{LUT} ( V ( CC 2 ) , T ( CC 2 ) ) - {SOC}_{LUT} ( V ( CC 1 ) , T ( CC 1 ) )} \qquad ( 3 )$$

Like equation (1),

$${\int }_{{CC}_{1}}^{{CC}_{2}} Idt$$

denotes the integration of current (e.g., net amp hour throughput) between the first instance and the second instance. Here, the time period between the first and second instances may only include the amount of time when the main contactor 127 is closed. As an example, a first instance may occur at 8 AM when the vehicle 112 is driven from a user's home to work for an hour. The vehicle may be parked for 8 hours, and then driven to home at 5 PM which takes another hour. The second instance may occur when the vehicle 112 is plugged in at home at 6 PM. In the above example, the total time is 2 hours (not including the 8 hours parking time). The difference in SOC between the first instance and the second instance may be represented as ΔSOC. The uncertainty associated with the SOC difference ΔSOC may be expressed as:

$$U ( Δ {SOC}_{CC 1 , CC 2} ) = 100 \% * \frac{\sqrt{{( U ( {SOC}_{LUT} ( V ( CC 2 ) , T ( CC 2 ) ) ) )}^{2} + {( U ( {SOC}_{LUT} ( V ( CC 1 ) , T ( CC 1 ) ) ) )}^{2}}}{{SOC}_{LUT} ( V ( CC 2 ) , T ( CC 2 ) ) - {SOC}_{LUT} ( V ( CC 1 ) , T ( CC 1 ) )} \qquad ( 4 )$$

From the above equation (4), it may be noted that the uncertainty U(ΔSOC) associated with the SOC difference ΔSOC may vary depending on the battery data collected at the first instance (e.g., CC1) and the subsequent second instance (e.g., CC2). Thus, the battery data corresponding to different time periods may affect the uncertainty U(ΔSOC) associated with the SOC difference ΔSOC. The present disclosure proposes a method for selectively estimating the capacity of the traction battery 124 based on battery data associated with a minimum uncertainty U(ΔSOC) between the beginning and end of the time period such that the estimation accuracy may be increased.

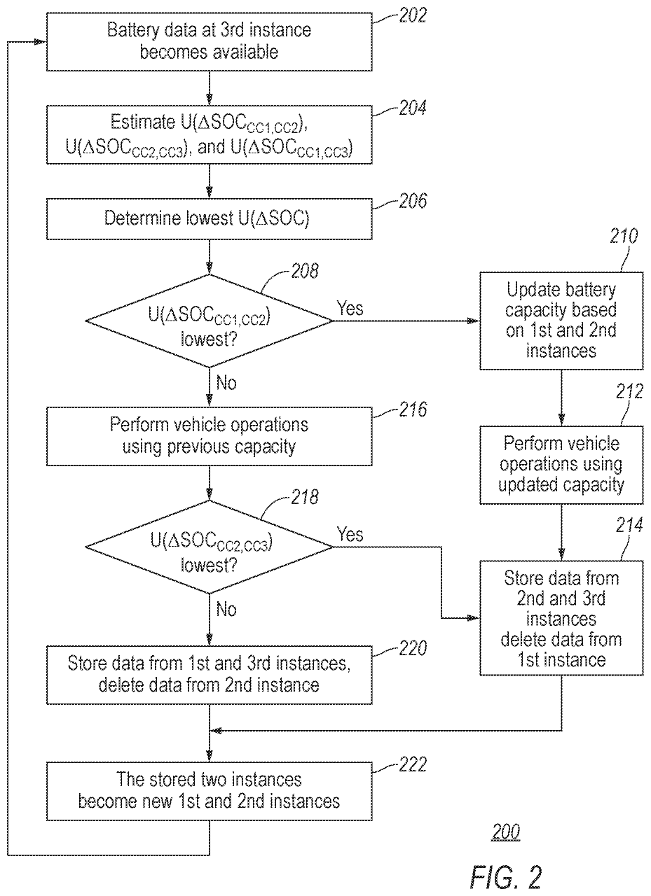

Referring to FIG. 2, an example flow diagram of a process for estimating the battery capacity and operating the vehicle of one embodiment of the present disclosure is illustrated. With continuing reference to FIG. 1, the process 200 may be independently implemented via the BECM 125. Additionally or alternatively, the process 200 may be collectively implemented via the BECM 125, the system controller 150 and/or other components of the vehicle 112 under essentially the same concept. The following description will be made with reference to the BECM 125 for simplicity. In the present example, battery data at three instances are used. The first instance, second instance, and third instance occurred sequentially. Before the operation 202 begins, it is assumed that the battery data associated with the first and second instance have already been recorded by the BECM 125.

At operation 202, the BECM 125 determines the battery data associated with the third instance has become available. The battery data may include various parameters. For instance, the battery data may include the battery voltage, temperature and amp-hour measured at the third instance. The BECM 125 may be configured to periodically measure the battery data responsive to one or more predefined measurement condition being met. For instance, the measurement condition may include a time lapse condition that allows the BECM 125 to perform new measurements after the elapse of a predefined time period. The measurement condition may further include a charge/discharge condition that allows the BECM 125 to perform new measurements after the vehicle is charged and/or discharged.

With the battery data associated with the first, second, and third instances collected, at operation 204, the BECM 125 estimates three individual uncertainties associated with the three time periods based on the above equation (4). More specifically, the BECM 125 estimates a first uncertainty U(ΔSOC_{CC1, CC2}) associated with a first time period starting at the first instance and finishing at the second instance, a second uncertainty U(ϕSOC_{CC2, CC3}) associated with a second time period starting at the second instance and finishing at the third instance, and a third uncertainty U(ΔSOC_{CC1, CC3}) associated with a third time period starting at the first instance and finishing at the third instance. In the present example, the third time period is equal to the sum of the first time period and second time period. Although the uncertainty for ΔSOC between different time instances are used for the calculations in the present embodiment, the present disclosure is not limited there to. In an alternative example, the capacity uncertainty associated with the different time instances (e.g., U(Q_{Est_CC1, CC2}) may be used under the similar concept. In the present example, the amp-hour integration component is assumed to be near zero and therefore ignored.

With the uncertainties U(ΔSOC) associated with the three time periods estimated, at operation 206, the BECM 125 compares the uncertainties and determines the lowest uncertainty among the three for recordation. For instance, at operation 208, if the BECM 125 determines the first uncertainty U(ΔSOC_{CC1, CC2}) associated with the first time period is the lowest among the three, the process 200 proceeds to operation 210 and the BECM 125 updates the estimated battery capacity based on the data from the first and second instances and disregards the battery data associated with the third instance.

With the estimated battery capacity Q_{Est} updated, at operation 212, the BECM 125 operates the vehicle 112 and/or the traction battery 124 based on the updated battery capacity Q_{Est}. The operations performed by the BECM 125 may include various examples. The BECM 125 may adjust the discharging of the traction battery 124 using the updated battery capacity Q_{Est} when the vehicle 112 is driven. For instance, responsive to determining the battery capacity Q_{Est} has been reduced since the last estimation, the BECM 125 may provide a shorter range estimate and reduce the maximum discharge power of the traction battery 124 to conserve electric energy. Alternatively, the BECM 125 may adjust the charging operations based on the updated battery capacity Q_{Est}. As an example, responsive to determining the battery capacity Q_{Est} has been reduced, the BECM 125 may reduce the power and/or total amount of the battery charging via the EVSE 138 and/or re-generative charging.

At operation 214, the BECM 125 stores the vehicle data from the second and third instances and deletes the vehicle data from the first instance. Since the vehicle data from the first instance is the oldest and has already been used to update the estimated battery capacity Q_{Est}, the data may be deleted from the vehicle memory to save storage space. The stored data from the second and third instances may include various entries. For instance, the BECM 125 may store data entries such as SOC, uncertainty, and throughput associated with the corresponding time instances in the onboard storage for future use.

If the first uncertainty U(ΔSOC_{CC1, CC2}) is not the lowest, the process 200 proceeds from operation 208 to operation 216 such that the BECM operates the vehicle 112 and/or the traction battery 124 based on the previously estimated battery capacity Q_{Est} without an update.

The process 200 proceeds from operation 216 to operation 218 to further determine if the second uncertainty U(ΔSOC_{CC2, CC3}) associated with the second time period is the lowest among the three. If the answer is yes, the process 200 proceeds to operation 214 as discussed above to store the vehicle data from the second and third instances and delete the vehicle data from the first instance.

If the answer for operation 218 is no indicating the third uncertainty U(ΔSOC_{CC1, CC3}) associated with the third time period is the lowest among the three, the process 200 proceeds to operation 220 to store the vehicle data from the first and third instances and delete the vehicle data from the second instance. For similar reasons, the vehicle data from the second instance being not the most recent and associated with a relatively higher uncertainty may be deleted to save storage space. Instead, the vehicle data from the first instance may be kept in storage for future reference.

The process 200 may be performed in a continuous manner. At operation 222, the BECM 125 assigns the stored two instances at the new first and second instances in preparation of the next battery capacity Q_{Est} estimation when the battery data associated with the new third instance becomes available. Thus, if the process 200 reaches operation 222 from operation 214, the second and third instances become the new first and second instances. Otherwise, if the process 200 reaches operation 222 from operation 220, the first and third instances become the new first and second instances.

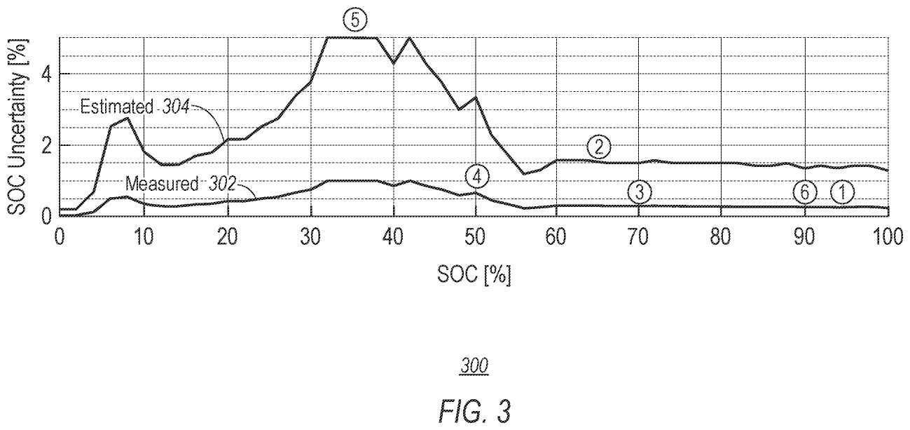

The operations of the process 200 may be applied to various examples. Referring to FIG. 3, an example graph 300 of a lookup table for SOC uncertainties of one embodiment of the present disclosure is illustrated. The horizontal axis of the graph 300 denotes the SOC of the traction battery 124 in units of percentage, and the vertical axis of the graph 300 denotes the SOC uncertainty U(SOC) in units of percentage. As illustrated in FIG. 3, two SOC uncertainty U(SOC) lookup tables are illustrated. More specifically, the graph 300 includes a measured lookup table 302 corresponding to situations in which the OCV measurement is available, and an estimated lookup table 304 corresponding to situations in which OCV measurement is unavailable and should be estimated. In general, the estimated lookup table 304 may be associated with higher uncertainties compared with the measured lookup table 302.

Whether the OCV measurement of the traction battery 124 is available may depend on various factors. For instance, the measurement availability may depend on vehicle usage factors including the length of time the vehicle is parked in between charging and driving usage, the customer usage scenarios, the polarization condition of the battery cells, or the like. For instance, when the usage scenario allows the traction battery 124 to sufficiently relax, a relatively accurate OCV measurement may be available and the BECM 125 may use the measured voltage to calculate the SOC and thus determine the SOC uncertainty U(SOC) accordingly. However, if the usage scenario does not allow the traction battery 124 to sufficiently relax, the accurate OCV measurement may be unavailable and the OCV may be estimated to determine the SOC and the associated SOC uncertainty U(SOC). In the present example, it is assumed that the measured OCV (and thus the measured uncertainty 302) is associated with a +/−3 mV uncertainty, and the estimated OCV (and thus the estimated uncertainty 304) is associated with +/−15 mV uncertainty.

In general, the traction battery 124 is sufficiently relaxed after the voltage of the battery has reached the OCV such that the SOC-OCV curve becomes valid. The traction battery 124 is considered polarized immediately after a charge or discharge activity. Therefore, the voltage of the traction battery 124 has not reached the OCV immediately after the charge or discharge activity. The voltage of the traction battery 124 may reach the OCV after the elapse of a period of time (e.g., 1 hour) with no charge or discharge activity.

Referring to Table 1 below, an example usage scenario of the vehicle 112 is illustrated:

TABLE 1
A vehicle usage scenario

| | Sufficiently | | | U(SOC) |
|---|---|---|---|---|
| Instance No. | Relaxed | Measured/Estimated | SOC (%) | (%) |
| 1 | Yes | Measured | 95 | 0.27 |
| 2 | No | Estimated | 65 | 1.58 |
| 3 | Yes | Measured | 70 | 0.30 |
| 4 | Yes | Measured | 50 | 0.67 |
| 5 | No | Estimated | 35 | 5.00 |
| 6 | Yes | Measured | 90 | 0.27 |

In the present example illustrated in Table 1, six time instances of the OCV are measured or estimated. At the first instance, the BECM 125 determines the traction battery 124 is sufficiently relaxed and therefore the OCV may be measured as the voltage across the battery terminals. The BECM 215 determines the SOC as 95% based on the measured OCV value and the SOC uncertainty U(SOC) as 0.27% using the measured lookup table 302. At the second instance, the BECM 125 determines the traction battery 124 is not sufficiently relaxed and therefore the OCV may only be estimated. The BECM 215 determines the SOC as 65% based on the estimated OCV value and the SOC uncertainty U(SOC) as 1.58% using the estimated lookup table 304. At the third instance, the BECM 125 determines the traction battery 124 is sufficiently relaxed and therefore the OCV may be measured as the voltage across the battery terminals. The BECM 215 determines the SOC as 70% based on the measured OCV value and the SOC uncertainty U(SOC) as 0.30% using the measured lookup table 302. At the fourth instance, the BECM 125 determines the traction battery 124 is sufficiently relaxed and therefore the OCV may be measured as the voltage across the battery terminals. The BECM 215 determines the SOC as 50% based on the measured OCV value and the SOC uncertainty U(SOC) as 0.67% using the measured lookup table 302. At the fifth instance, the BECM 125 determines the traction battery 124 is not sufficiently relaxed and therefore the OCV may only be estimated. The BECM 215 determines the SOC as 35% based on the estimated OCV value and the SOC uncertainty U(SOC) as 5.00% using the estimated lookup table 304. At the sixth instance, the BECM 125 determines the traction battery 124 is sufficiently relaxed and therefore the OCV may be measured as the voltage across the battery terminals. The BECM 215 determines the SOC as 90% based on the measured OCV value and the SOC uncertainty U(SOC) as 0.27% using the measured lookup table 302. Each of the first to sixth instances are also labeled on the graph 300 at the corresponding locations.

With both the SOC and the corresponding SOC uncertainty U(SOC) available, the uncertainty associated with the SOC difference ΔSOC may be determined for each time period using the above equation (4). For instance, the uncertainty associated with the SOC difference ΔSOC for a first period starting at the first instance and finishing at the second instance may be calculated using equation (4) as

$$U ( Δ {SOC}_{CC 1 , CC 2} ) = 100 \% * \frac{\sqrt{{( 0.27 )}^{2} + {( 1.58 )}^{2}}}{95 - 65} = 5.341 \%$$

Similarly, the uncertainty associated with the SOC difference ΔSOC for a second period starting at the first instance and finishing at the third instance may be calculated using equation (4) as

$$U ( Δ {SOC}_{CC 1 , CC 3} ) = 100 \% * \frac{\sqrt{{( 0.27 )}^{2} + {( 0.3 )}^{2}}}{95 - 70} = 1.622 \%$$

The BECM may perform the calculation in the similar manner for each time period and generate the results as illustrated in Table 2 below:

TABLE 2
U(ΔSOC) results for different periods.

| | Finish | 1st | 2nd | 3rd | 4th | 5th | 6th |
|---|---|---|---|---|---|---|---|
| | SOC (%) | 95 | 65 | 70 | 50 | 35 | 90 |
| Start | U(SOC) | 0.27 | 1.58 | 0.30 | 0.67 | 5.00 | 0.27 |
| SOC (%) | (%) | | | | | | |
| 1st 95 | 0.27 | N/A | 5.341 | 1.622 | 1.601 | 8.346 | 7.713 |
| 2nd 65 | 1.58 | N/A | N/A | 32.145 | 11.427 | 17.479 | 6.410 |
| 3rd 70 | 0.30 | N/A | N/A | N/A | 3.655 | 14.311 | 2.027 |
| 4th 50 | 0.67 | N/A | N/A | N/A | N/A | 33.628 | 1.801 |
| 5th 35 | 5.00 | N/A | N/A | N/A | N/A | N/A | 9.104 |
| 6th 90 | 0.27 | N/A | N/A | N/A | N/A | N/A | N/A |

For the above Table 2, the U(ΔSOC) varies dramatically depending on the starting and finishing time instances. More specifically, the best time period starting at the first instance and finishing at the fourth instance is associated with the lowest SOC difference uncertainty (e.g., 1.601%) whereas the worst time period starting at the fourth instance and finishing at the fifth instance is associated with the highest SOC difference uncertainty (e.g., 33.628%).

The BECM 125 may select one or more time periods associated with the lowest SOC difference uncertainty U(ΔSOC) for battery capacity estimation and delete the battery data for other instances/time periods. For instance, if the BECM 125 is configured to select a predetermined number of time periods of two, the best time period starting at the first instance and finishing at the fourth instance (e.g., 1.601%) and the second-best time period starting at the fourth instance and finishing at the sixth instance (e.g., 1.801%) will be selected. Alternatively, the BECM 125 may be configured to select a flexible number of time periods based on the one or more predefined thresholds for the SOC difference uncertainty U(ΔSOC). For instance, a 5% threshold may be applied to the various time periods. In this case, the third-best time period starting at the third instance and finishing at the fourth instance (e.g., 3.655%) and the fourth-best time period starting at the third instance and finishing at the sixth instance (e.g., 2.027%) will also be selected. Alternatively, all capacity estimates with local minimum uncertainty may be used by the BECM 125. An additional filter may be applied to decide what to do with individual estimates.

In an alternative example, the BECM 125 may determine the uncertainty between different SOCs (as well as different estimated capacities) using the amp-hour throughput integration component presented in equation (1) under substantially the same concept. In one example, the amp-hour throughput integration component maybe used to determine the uncertainty in lieu of using the ΔSOC. In an alternative example, the amp-hour throughput integration component maybe used to determine the uncertainty in addition to using the ΔSOC.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. An automotive power system comprising:
a traction battery; and
a controller programmed to adjust a maximum discharge power of the traction battery according to an estimated capacity that depends on data of the traction battery from instances of time selected based on a delta state of charge uncertainty associated with the instances of time.

2. The automotive power system of claim 1, wherein the controller is further programmed to selectively store the data based on the delta state of charge uncertainty.

3. The automotive power system of claim 1, wherein the data include states of charge of the traction battery.

4. The automotive power system of claim 3, wherein some of the states of charge are measured and other of the states of charge are estimated.

5. The automotive power system of claim 1, wherein the estimated capacity further depends on a charge or discharge experienced by the traction battery during a time period that corresponds with the instances of time.

6. The automotive power system of claim 1, wherein the delta state of charge uncertainty depends on states of charge of the traction battery.

7. A method comprising:
adjusting a maximum discharge power for a traction battery according to an estimated capacity that depends on data of the traction battery from instances of time corresponding to a delta state of charge uncertainty value less than a predefined threshold.

8. The method of claim 7 further comprising selectively storing the data based on the delta state of charge uncertainty value.

9. The method of claim 7, wherein the data includes states of charge of the traction battery.

10. The method of claim 9 further comprising measuring some of the states of charge and estimating other of the states of charge.

11. The method of claim 7, wherein the estimated capacity further depends on a charge or discharge experienced by the traction battery during a time period that corresponds with the instances of time.

12. The method of claim 7, wherein the delta state of charge uncertainty value depends on states of charge of the traction battery.

13. A vehicle comprising:
an electric machine;
a traction battery; and
a controller programmed to command discharge of power from the traction battery for the electric machine according to data of the traction battery from instances of time selected based on a net amp-hour throughput uncertainty associated with the instances of time.

14. The vehicle of claim 13, wherein the controller is further programmed to selectively store the data based on the net amp-hour throughput uncertainty.

15. The vehicle of claim 13, wherein the data include a current of the traction battery.
